(19) United States
(12) Patent Application Publication
(10) Pub. No.: US 2025/0292843 A1
(43) Pub. Date: Sep. 18, 2025

(54) SEMICONDUCTOR DEVICE AND MEMORY SYSTEM

(71) Applicant: Kioxia Corporation, Tokyo (JP)

(72) Inventor: Toshihiro YAGI, Yokohama Kanagawa (JP)

(21) Appl. No.: 19/074,227

(22) Filed: Mar. 7, 2025

(30) Foreign Application Priority Data
Mar. 15, 2024 (JP) 2024-041609

(51) Int. Cl. G11C 16/32

(52) U.S. Cl. CPC G11C 16/32

(57) ABSTRACT

A semiconductor device is capable of suppressing deterioration in signal quality due to an effect of reflection even when it employs a communication scheme in which a signal at a first level has a first voltage margin relative to a first reference voltage that is equal to a ground voltage and the signal at a second level has a second voltage margin relative to a second reference voltage, the second voltage margin being greater than the first voltage margin. The semiconductor device includes an output buffer configured to transmit data through the signal according to on/off states of a first transistor group and a second transistor group, and a control circuit configured to perform pull-down of a voltage level of the signal by a third reference voltage lower than the first reference voltage when the signal outputted from the output buffer transitions from the second level to the first level.

### CROSS-REFERENCE TO RELATED APPLICATION(S)

This application is based upon and claims the benefit of priority from Japanese Patent Application No. 2024-041609, filed Mar. 15, 2024, the entire contents of which are incorporated herein by reference.

### FIELD

Embodiments described herein relate generally to a semiconductor device and a memory system.

### BACKGROUND

Conventionally, a calibration circuit for suppressing an impedance fluctuation due to a temperature variation or a voltage variation may sometimes be adopted as an output buffer to be used in a high-speed interface. The calibration circuit uses a plurality of resistance elements and adjusts impedance by switching among resistance elements to be connected to the output buffer.

While signal quality is relatively good when connection topology of communication transmission paths is one-to-one, in a case of a bifurcation of one-to-two or the like, there is a problem in that signal quality deteriorates due to reflection from a bifurcated end. The deterioration in signal quality is particularly prominent in communication schemes with small amplitudes.

### BRIEF DESCRIPTION OF THE DRAWINGS

FIG. 1 is a block diagram showing a configuration of a memory system including a semiconductor device according to a first embodiment.

FIG. 2A is a diagram showing an example of a waveform of a communication scheme with a large amplitude.

FIG. 2B is a diagram showing an example of a waveform of a communication scheme with a small amplitude.

FIG. 3 is a diagram showing an example of a configuration of an output buffer according to a comparative example.

FIG. 4 is a diagram showing an example of a configuration in which a circuit that suppresses reflection is added to the output buffer according to the comparative example.

FIG. 5 is a circuit diagram showing an example of a configuration of a negative-voltage pull-down circuit according to the present embodiment.

FIG. 6 is a timing chart showing an example of an operation of a negative-voltage pull-down circuit according to the present embodiment.

FIG. 7 is a circuit diagram showing an example of a configuration of a delay adjustment circuit.

FIG. 8 is a timing chart showing an example of an operation of the delay adjustment circuit.

FIG. 9 is a circuit diagram showing an example of a configuration of a variable delay circuit.

FIG. 10 is a diagram showing an example of eye patterns according to the comparative example and the embodiment.

FIG. 11 is a timing chart showing an operation according to a modification.

FIG. 12 is a block diagram showing a configuration of a memory system including a semiconductor device according to a second embodiment.

### DETAILED DESCRIPTION

Embodiments provide a semiconductor device and a memory system capable of suppressing deterioration in signal quality due to an effect of reflection even when they employ communication schemes with small amplitudes.

In general, according to one embodiment, a semiconductor device is configured to transmit data by a communication scheme in which a signal at a first level has a first voltage margin relative to a first reference voltage that is equal to a ground voltage and the signal at a second level has a second voltage margin relative to a second reference voltage, the second voltage margin being greater than the first voltage margin, and includes an output buffer and a control circuit. The output buffer is configured to transmit data through the signal according to on/off states of a first transistor group and a second transistor group. The control circuit is configured to perform pull-down of a voltage level of the signal by a third reference voltage that is lower than the first reference voltage when the signal outputted from the output buffer transitions from the second level to the first level. When a signal transitions from the second level to the first level, a low-level signal instantaneously rises to a high level near a determination point due to reflection from a bifurcated end and quality of the signal deteriorates. In order to remedy such a situation, pull-down by a negative voltage is performed in accordance with a timing of reflection from the bifurcated end. Accordingly, the quality of the low-level signal is improved.

Hereinafter, embodiments of the present invention will be described in detail with reference to the drawings.

### First Embodiment

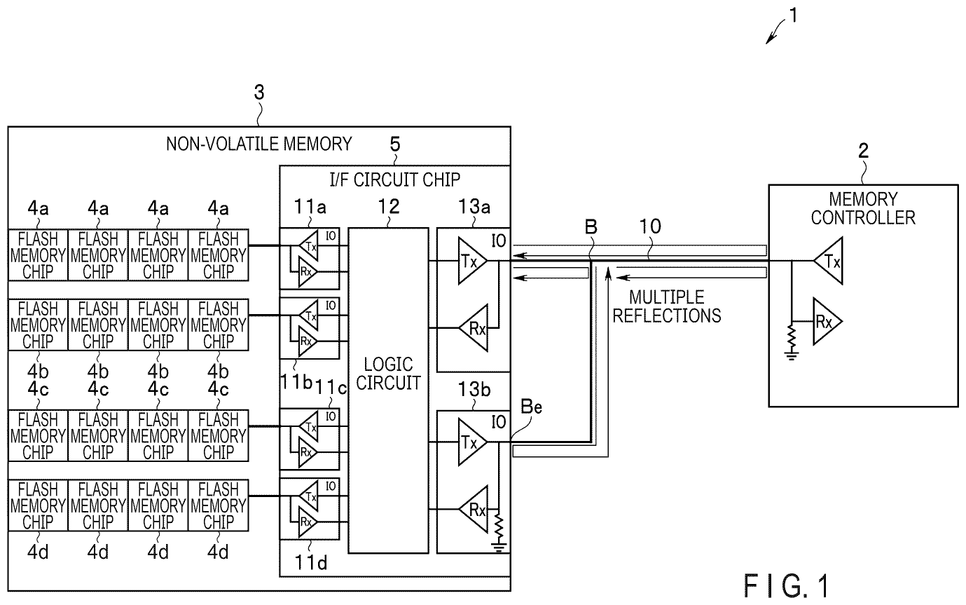

FIG. 1 is a block diagram showing a configuration of a memory system including a semiconductor device according to a first embodiment.

While an example in which the memory system is applied to an interface circuit between a non-volatile memory chip such as a NAND flash memory chip and a memory controller will be described in the present embodiment, the memory system is applicable to various interface circuits.

A memory system 1 includes a memory controller 2 and a non-volatile memory 3. The memory controller 2 is implemented as a semiconductor chip in this example. The memory controller 2 transmits/receives data to/from the non-volatile memory 3 based on a write request or a read request of data from a host.

The memory controller 2 and the non-volatile memory 3 are connected by, for example, a wiring 10 on a printed circuit board (or inside the printed circuit board). The wiring 10 includes a bifurcation B for connecting the wiring 10 to two input/output circuits 13a and 13b of the non-volatile memory 3.

The non-volatile memory 3 includes a plurality of flash memory chips 4a, 4b, 4c, and 4d (hereinafter, referred to as a flash memory chip 4 when no distinction is made among the flash memory chips) and an I/F circuit chip 5. The non-volatile memory 3 is implemented as a package that houses a plurality of semiconductor chips. For example, the non-volatile memory 3 has a structure in which a plurality of flash memory chips 4 are stacked and are collectively sealed with the I/F circuit chip 5 in a package.

The I/F circuit chip 5 includes input/output circuits 11a, 11b, 11c, and 11d (hereinafter, referred to as an input/output circuit 11 when no distinction is made among the input/output circuits), a logic circuit 12, and input/output circuits 13a and 13b (hereinafter, referred to as an input/output circuit 13 when no distinction is made between the input/output circuits). The input/output circuits 11a, 11b, 11c, and 11d respectively transmit/receive data and various signals to/from the flash memory chips 4a, 4b, 4c, and 4d and the logic circuit 12. The input/output circuits 13a and 13b respectively transmit/receive data and various signals to/from the memory controller 2 and the logic circuit 12.

The input/output circuits 11 and 13 respectively include an output buffer (transmission buffer) Tx and a reception buffer Rx. For example, when transferring data from the input/output circuit 13a to the memory controller 2, the output buffer Tx of the input/output circuit 13a is turned on and the output buffer Tx of the input/output circuit 13b is turned off.

When reading data from the flash memory chip 4, a read enable signal is transmitted from the memory controller 2 to the non-volatile memory 3. In synchronization with the read enable signal, the non-volatile memory 3 reads the data from the flash memory chip 4 and transfers the data to the memory controller 2 via the I/F circuit chip 5.

In the present embodiment, for example, the memory controller 2 and the non-volatile memory 3 transfer data by a Low Tapped Termination (LTT) communication scheme. LTT is a communication scheme which transfers data by a small amplitude, the amplitude having been reduced in order to increase data transfer speed.

As described above, the wiring 10 between the memory controller 2 and the non-volatile memory 3 includes the bifurcation B. Therefore, when transferring data from the non-volatile memory 3 to the memory controller 2, multiple reflections occur due to reflection from a bifurcated end Be and signal quality deteriorates. Such a deterioration in signal quality is particularly problematic in communication schemes with a small amplitude such as LTT.

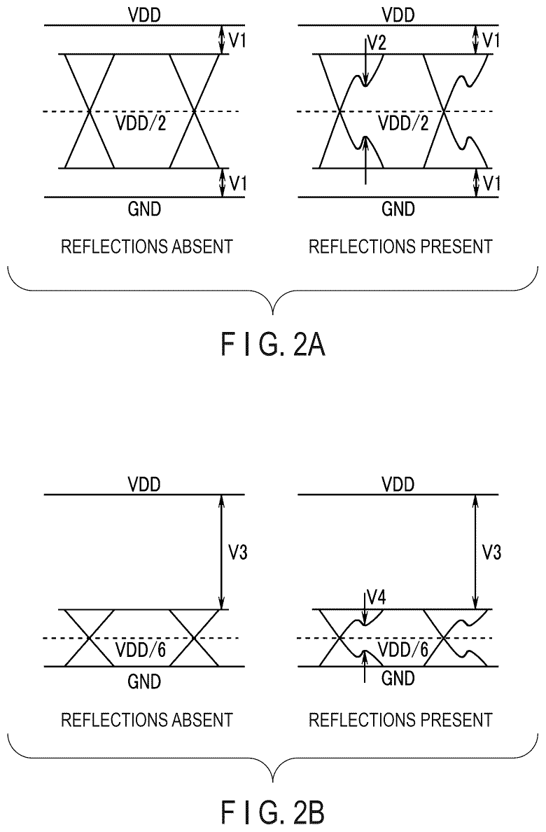

FIG. 2A is a diagram showing an example of a waveform of a communication scheme with a large amplitude. FIG. 2B is a diagram showing an example of a waveform of a communication scheme with a small amplitude.

The waveform shown in FIG. 2A represents a waveform of a communication scheme with a large amplitude such as Center Tapped Termination (CTT). A communication scheme with a large amplitude such as CTT oscillates around power supply voltage level of VDD/2. In this communication scheme with a large amplitude, amplitude is reduced to a certain extent by On-Die Termination on a receiving side and communication is performed by respectively setting a voltage difference of a voltage V1 with respect to power supply VDD and ground GND.

With such a communication scheme with a large amplitude, a voltage difference V2 can be secured even if there is a signal reflection from the bifurcated end Be. In other words, with a communication scheme with a large amplitude, even if there is signal reflection, transmission standards can be satisfied since an eye opening (represented by the voltage difference V2) is sufficiently large. However, a large amplitude has disadvantages in that current increases and higher speeds are difficult to realize.

On the other hand, the waveform shown in FIG. 2B represents a waveform of a communication scheme with a small amplitude such as LTT. A communication scheme with a small amplitude such as LTT oscillates around power supply voltage level of VDD/6. The communication scheme with a small amplitude has a voltage difference of a voltage V3 with respect to power supply VDD. On the other hand, there is no voltage difference with respect to ground GND.

With a communication scheme with a small amplitude such as LTT, it is difficult to secure a voltage difference V4 that is large enough when there is a signal reflection from the bifurcated end Be. Particularly, with respect to a reflection of a low signal, the reflection cannot be suppressed even with a pull-down to the GND level. As a result, the eye opening decreases, and transmission standards cannot be satisfied.

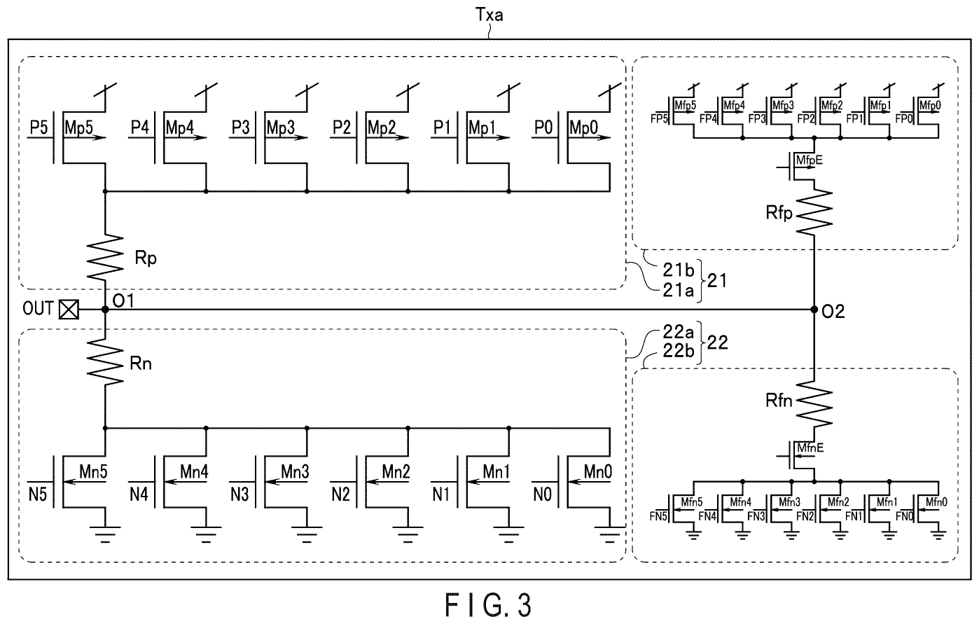

FIG. 3 is a diagram showing an example of a configuration of an output buffer according to a comparative example.

An output buffer Txa according to the comparative example includes a P buffer group 21 and an N buffer group 22. The P buffer group 21 includes a coarse P buffer 21a and a fine P buffer 21b. The N buffer group 22 includes a coarse N buffer 22a and a fine N buffer 22b.

The coarse P buffer 21a and the coarse N buffer 22a are static correction circuits and are used to coarsely adjust resistance values during a period of no signal communication through the output buffer Txa. On the other hand, the fine P buffer 21b and the fine N buffer 22b are dynamic correction circuits and are used to finely adjust resistance values while a signal is being communicated through the output buffer Txa. The coarse P buffer 21a and the coarse N buffer 22a make up a first transistor group and the fine P buffer 21b and the fine N buffer 22b make up a second transistor group. In addition, the output buffer Txa transmits data according to on/off states of the first transistor group and the second transistor group.

The coarse P buffer 21a includes PMOS transistors Mp0 to Mp5 and a resistor Rp. Sources of the PMOS transistors Mp0 to Mp5 are connected to a power supply terminal and drains are commonly connected. The drains of the PMOS transistors Mp0 to Mp5 are connected to a node O1 via the resistor Rp. Control signals P0 to P5 are respectively inputted to gates of the PMOS transistors Mp0 to Mp5 to control on/off states.

The fine P buffer 21b includes PMOS transistors Mfp0 to Mfp5, a PMOS transistor MfpE, and a resistor Rfp. Sources of the PMOS transistors Mfp0 to Mfp5 are connected to a power supply terminal and drains are commonly connected. A source of the PMOS transistor MfpE, which functions as a switching transistor, is connected to drains of the PMOS transistors Mfp0 to Mfp5. A drain of the PMOS transistor MfpE is connected to a node O2 via the resistor Rfp. Control signals FP0 to FP5 are respectively inputted to gates of the PMOS transistors Mfp0 to Mfp5 to control on/off states.

The coarse N buffer 22a includes NMOS transistors Mn0 to Mn5 and a resistor Rn. Sources of the NMOS transistors Mn0 to Mn5 are connected to a reference voltage and drains are commonly connected. The drains of the NMOS transistors Mn0 to Mn5 are connected to the node O1 via the resistor Rn. Control signals N0 to N5 are respectively inputted to gates of the NMOS transistors Mn0 to Mn5 to control on/off states.

The fine N buffer 22b includes NMOS transistors Mfn0 to Mfn5, an NMOS transistor MfnE, and a resistor Rfn. Sources of the NMOS transistors Mfn0 to Mfn5 are connected to a reference voltage and drains are commonly connected. A source of the NMOS transistor MfnE, which functions as a switching transistor, is connected to drains of the NMOS transistors Mfn0 to Mfn5. A drain of the NMOS transistor MfnE is connected to the node O2 via the resistor Rfn. Control signals FN0 to FN5 are respectively inputted to gates of the NMOS transistors Mfn0 to Mfn5 to control on/off states.

In the output buffer Txa configured as described above, it is known to add a pull-down circuit in order to suppress a deterioration in signal quality due to the reflection described above.

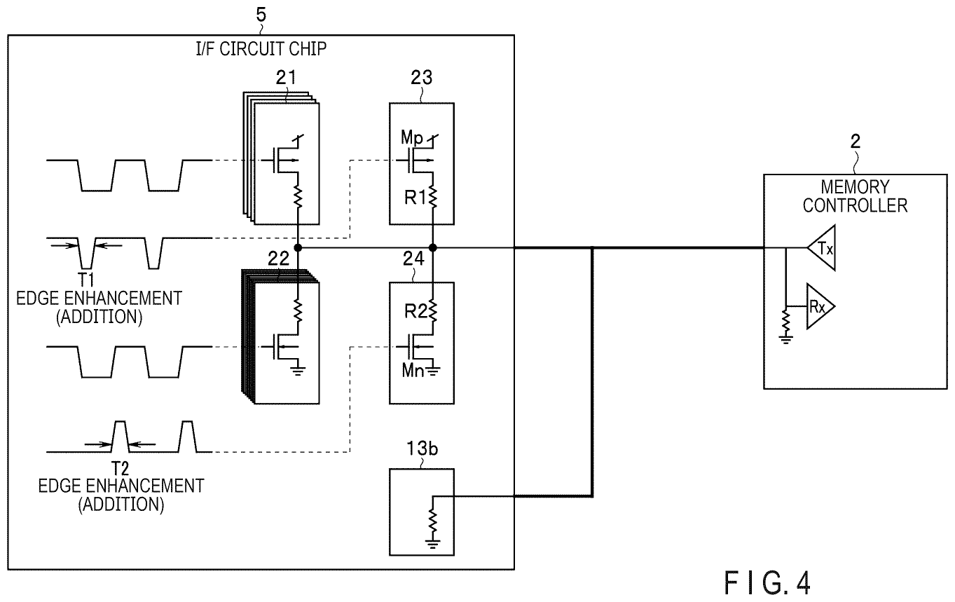

FIG. 4 is a diagram showing an example of a configuration in which a circuit that suppresses reflection is added to the output buffer according to the comparative example.

In the output buffer Txa, four P buffer groups 21 are connected in parallel and eight N buffer groups 22 are connected in parallel. In addition, a pull-up circuit 23 is added to the P buffer groups 21 and a pull-down circuit 24 is added to the N buffer groups 22.

The pull-up circuit 23 includes a PMOS transistor Mp and a resistor R1. A control signal T1 for performing edge enhancement when any of the PMOS transistors of the P buffer group 21 is turned on is inputted to the pull-up circuit 23.

The pull-up circuit 23 is turned on when the control signal T1 for performing edge enhancement is inputted and pulls up a signal to the power supply VDD. Accordingly, the pull-up circuit 23 suppresses signal reflection from the bifurcated end Be that occurs immediately after any of the PMOS transistors of the P buffer group 21 is turned on.

On the other hand, the pull-down circuit 24 includes an NMOS transistor Mn and a resistor R2. A control signal T2 for performing edge enhancement when any of the NMOS transistors of the N buffer group 22 is turned on is inputted to the pull-down circuit 24.

The pull-down circuit 24 is turned on when the control signal T2 for performing edge enhancement is inputted and pulls down a signal to ground GND. Accordingly, the pull-down circuit 24 suppresses signal reflection from the bifurcated end Be that occurs immediately after any of the NMOS transistors of the N buffer group 22 is turned on.

The pull-up circuit 23 and the pull-down circuit 24 can be realized by adding them to and controlling an ordinary buffer. The circuits are effective with respect to a communication scheme with a large amplitude that provides a voltage difference with respect to the power supply VDD and the ground GND shown in FIG. 2A.

On the other hand, with the communication scheme with a small amplitude shown in FIG. 2B, while there is a voltage difference of a voltage V3 with respect to power supply VDD, there is no voltage difference with respect to ground GND. Therefore, in a communication scheme with a small amplitude such as LTT, while the pull-up circuit 23 functions effectively, the pull-down circuit 24 does not function effectively. In other words, since there is no voltage difference with respect to ground GND, the effect of suppressing deterioration in signal quality due to reflection is small even if a pull-down is performed with respect to ground GND.

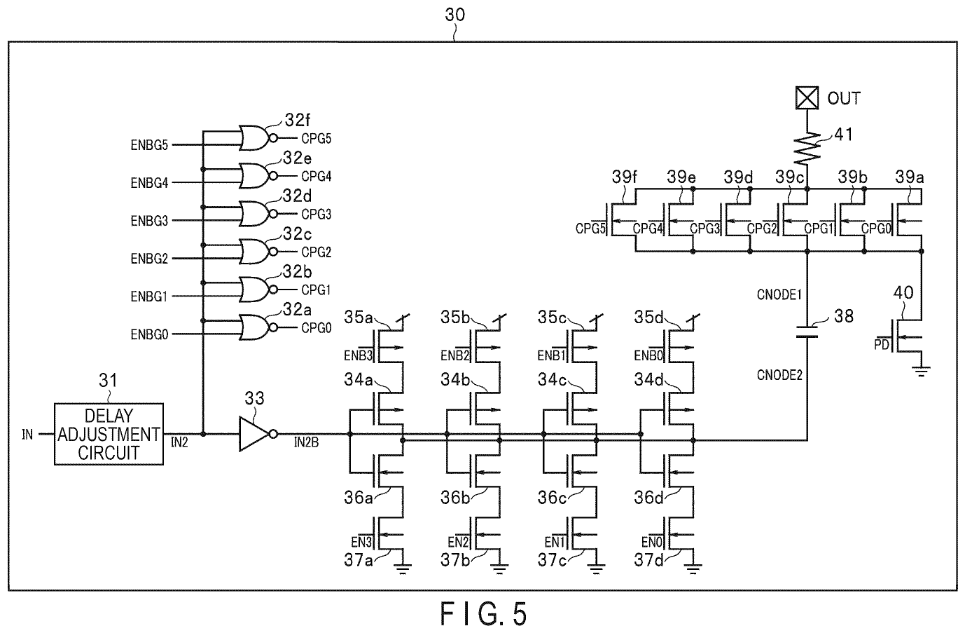

The output buffer Tx according to the present embodiment described below can suppress a deterioration in signal quality due to reflection even with a communication scheme with a small amplitude by using a negative-voltage pull-down circuit 30 shown in FIG. 5 instead of the pull-down circuit 24 according to the comparative example.

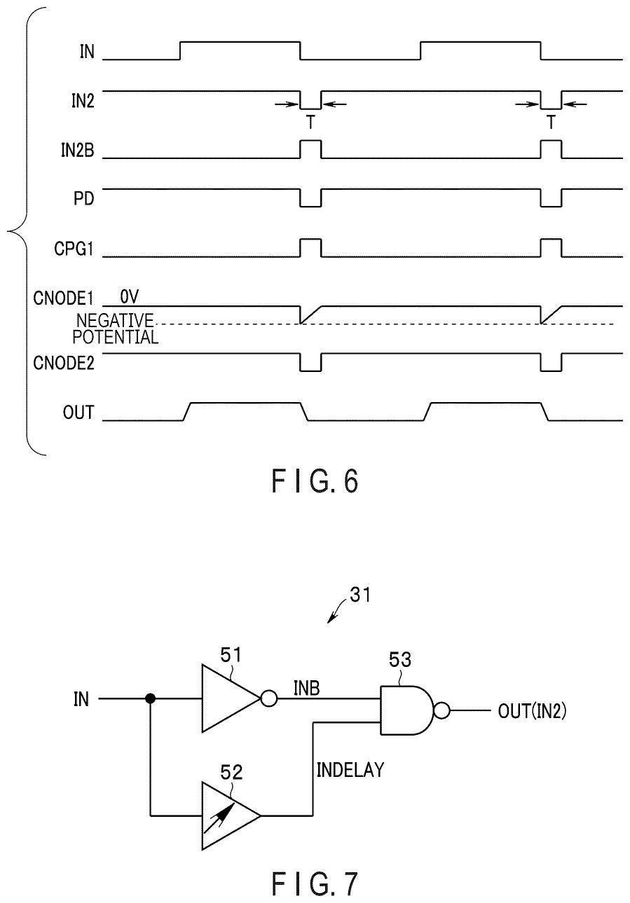

FIG. 5 is a circuit diagram showing an example of a configuration of a negative-voltage pull-down circuit according to the present embodiment. FIG. 6 is a timing chart showing an example of an operation of a negative-voltage pull-down circuit according to the present embodiment.

The negative-voltage pull-down circuit 30 includes a delay adjustment circuit 31, NOR circuits 32a to 32f, an inverter circuit 33, PMOS transistors 34a to 34d and 35a to 35d, NMOS transistors 36a to 36d and 37a to 37d, a capacitor 38, NMOS transistors 39a to 39f, an NMOS transistor 40, and a resistor 41.

The negative-voltage pull-down circuit 30 is a control circuit that performs pull-down by a negative voltage that is lower than ground when outputted data transitions from a high level (to a low level.

The delay adjustment circuit 31 is a circuit that generates a delay period T being a timing at which a negative voltage to be described later is generated in order to match a timing of signal reflection with a timing of edge enhancement of the negative-voltage pull-down circuit 30. The delay adjustment circuit 31 generates an output signal IN2 shown in FIG. 6 from an input signal IN and outputs the output signal IN2. In addition, the output signal IN2 is inputted to a gate of the NMOS transistor 40 as a control signal PD. A configuration of the delay adjustment circuit 31 that generates the output signal IN2 will be described later.

The output signal IN2 of the delay adjustment circuit 31 is inputted to one of the input terminals of the NOR circuits 32a to 32f. Enable signals ENBG0 to ENBG5 are respectively inputted to the other input terminals of the NOR circuits 32a to 32f. The NOR circuits 32a to 32f respectively perform negative OR operations of the enable signals ENBG0 to ENBG5 and the output signal IN2, and output control signals CPG0 to CPG5.

The control signals CPG0 to CPG5 are respectively inputted to gate terminals of the NMOS transistors 39a to 39f. Any of the NMOS transistors 39a to 39f may be turned on by the control signals CPG0 to CPG5. In other words, the control signals CPG0 to CPG5 are controlled by the enable signals ENBG0 to ENBG5 and determine which of the NMOS transistors 39a to 39f is to be turned on.

The NMOS transistors 39a to 39f function as a switch for correcting process variability during manufacturing. Which of the NMOS transistors 39a to 39f is to be turned on is determined by a calibration (coarse calibration) of a resistance value of the output buffer Tx. For example, by enabling the enable signal ENBG1, as shown in FIG. 6, the control signal CPG1 that is at a low level outside of the delay period T but at a high level during the delay period T is inputted to the gate of the NMOS transistor 39b.

The inverter circuit 33 outputs an output signal IN2B that is an inversion of the output signal IN2 of the delay adjustment circuit 31.

Inverter circuits are respectively made up of the PMOS transistor 34a and the NMOS transistor 36a, the PMOS transistor 34b and the NMOS transistor 36b, the PMOS transistor 34c and the NMOS transistor 36c, and the PMOS transistor 34d and the NMOS transistor 36d. The four inverter circuits constructed in this manner are connected in parallel.

Control signals ENB0 to ENB3 are inputted to gates of the PMOS transistors 35a to 35d. Control signals EN0 to EN3 are inputted to gates of the NMOS transistors 37a to 37d. Due to the control signals ENB0 to ENB3 and EN0 to EN3, any one of the four inverter circuits connected in parallel is turned on, inverts the output signal IN2B of the inverter circuit 33, and outputs the inverted output signal IN2B to the capacitor 38 via a node CNODE2. Therefore, as shown in FIG. 6, the node CNODE2 is set to a high level outside of the delay period T.

A source of the NMOS transistor 40 is connected to ground GND and a drain thereof is connected to a node CNODE1. The NMOS transistor 40 is turned on outside of the delay period T by the control signal PD. Therefore, as shown in FIG. 6, the node CNODE2 is set to a low level outside of the delay period T. Accordingly, the capacitor 38 is charged during a period outside of the delay period T.

In addition, logic of the node CNODE2 is inverted during the delay period T and changes from the high level to the low level. Furthermore, the NMOS transistor 40 is turned off during the delay period T by the control signal PD and a drain of the NMOS transistor 40 is set to a high-impedance state. Accordingly, as shown in FIG. 6, the node CNODE1 is changed to a negative voltage at a moment of discharge of the capacitor 38 during the delay period T. As a result, an output terminal OUT can be pulled down and a deterioration of signal quality due to the effect of reflection can be suppressed.

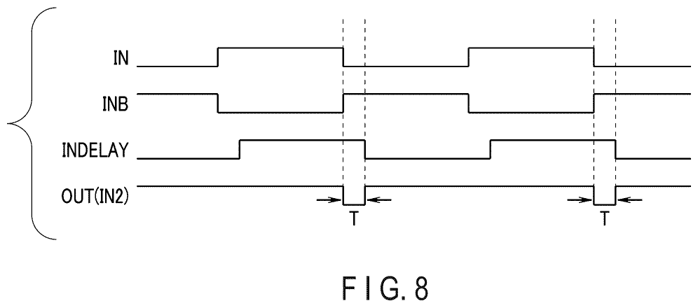

FIG. 7 is a circuit diagram showing an example of a configuration of a delay adjustment circuit. FIG. 8 is a timing chart showing an example of an operation of the delay adjustment circuit.

The delay adjustment circuit 31 includes an inverter circuit 51, a variable delay circuit 52, and a NAND circuit 53. The input signal IN is inputted to the inverter circuit 51 and the variable delay circuit 52.

The inverter circuit 51 inverts the input signal IN and outputs the inverted inversion signal INB (refer to FIG. 8) to the NAND circuit 53. Accordingly, the inversion signal INB that is an inversion of the input signal IN is inputted to the NAND circuit 53.

The variable delay circuit 52 delays the input signal IN by a predetermined period. Specifically, as shown in FIG. 8, the variable delay circuit 52 generates a delay signal INDELAY that is the input signal IN delayed by the delay period T and outputs the delay signal INDELAY to the NAND circuit 53. Accordingly, the delay signal INDELAY created by delaying the input signal IN by the delay period T is inputted to the NAND circuit 53.

The NAND circuit 53 performs a negative AND operation of the inversion signal INB and the delay signal INDELAY and outputs a result of the operation as an output signal OUT (IN2). Specifically, the NAND circuit 53 outputs a low-level signal only during a period in which the inversion signal INB and the delay signal INDELAY are at a high level and outputs a high-level signal during other periods.

As a result, as shown in FIG. 8, a low-level output signal OUT (IN2) is outputted from the delay adjustment circuit 31 only during the delay period T in which the input signal IN is delayed and a high-level output signal OUT (IN2) is outputted from the delay adjustment circuit 31 during other periods.

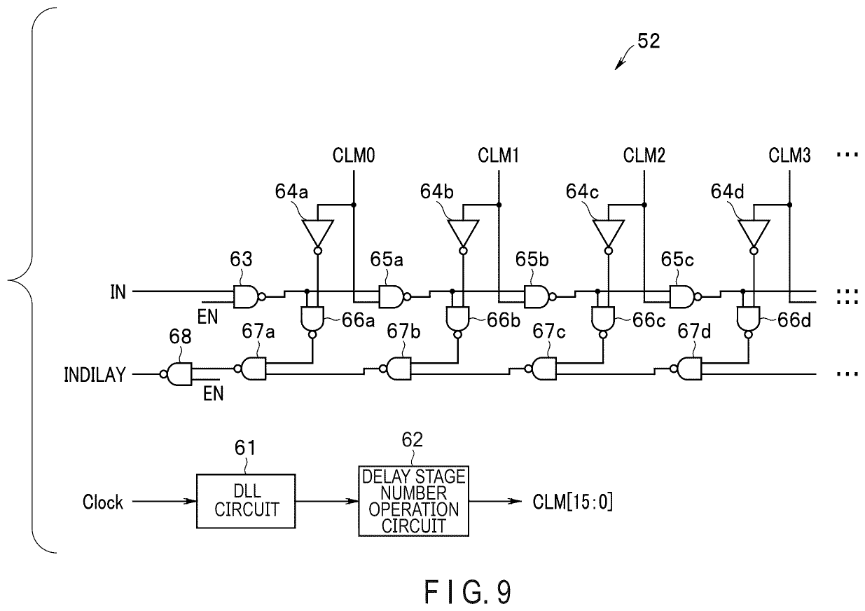

FIG. 9 is a circuit diagram showing an example of a configuration of a variable delay circuit.

The variable delay circuit 52 includes a DLL (Delay Locked Loop) circuit 61 and a delay stage number operation circuit 62. In addition, the variable delay circuit 52 includes a NAND circuit 63, a plurality of inverter circuits 64a, 64b, 64c, 64d, . . . , a plurality of NAND circuits 65a, 65b, 65c, . . . , a plurality of NAND circuits 66a, 66b, 66c, 66d, . . . , a plurality of NAND circuits 67a, 67b, 67c, 67d, . . . , and a NAND circuit 68.

The input signal IN and an enable signal EN are inputted to the NAND circuit 63. The NAND circuit 63 performs a negative AND operation of the input signal IN and the enable signal EN, and outputs a result of the operation to the NAND circuits 65a and 66a.

A control signal CLM0 is inputted to the inverter circuit 64a and the NAND circuit 65a. The inverter circuit 64a inverts the control signal CLM0 and outputs the inverted control signal CLM0 to the NAND circuit 66a.

The NAND circuit 65a performs a negative AND operation of the output signal of the NAND circuit 63 and the control signal CLM0, and outputs a result of the operation to the NAND circuits 65b and 66b.

The NAND circuit 66a performs a negative AND operation of the output signal of the NAND circuit 63 and the output signal of the inverter circuit 64a, and outputs a result of the operation to the NAND circuit 67a.

The output signal of the NAND circuit 66a and the output signal of the NAND circuit 67b are inputted to the NAND circuit 67a. The NAND circuit 67a performs a negative AND operation of the output signal of the NAND circuit 66a and the output signal of the NAND circuit 67b, and outputs a result of the operation to the NAND circuit 68.

The NAND circuit 68 performs a negative AND operation of the output signal of the NAND circuit 67a and the enable signal EN, and outputs a result of the operation as a delay signal INDELAY.

Configurations of the inverter circuit 64b and NAND circuits 65b, 66b, 67b, and thereafter are similar to configurations of the inverter circuit 64a and NAND circuits 65a, 66a, and 67a.

A clock signal CLK is inputted to the DLL circuit 61. The DLL circuit 61 calculates a delay time of a NAND circuit from one period of the clock signal CLK. In addition, the DLL circuit 61 calculates the number of stages of the NAND circuit necessary for the delay time T and outputs the calculated number of stages to the delay stage number operation circuit 62.

Based on the calculation result of the DLL circuit 61, the delay stage number operation circuit 62 outputs a control signal CLM [15:0] for controlling the number of stages by which the NAND circuit is to be delayed. For example, when delaying the input signal IN by one stage, a control signal CLM0 is set to “1” and control signals CLM1 to CLM15 are set to “0”. In addition, when delaying the input signal IN by two stages, the control signals CLM0 and CLM1 are set to “1” and the control signals CLM2 to CLM15 are set to “0”.

In this manner, the variable delay circuit 52 controls the number of delay stages of the input signal IN based on the control signal CLM [0:15] and adjusts the delay period T. Accordingly, the timing of the reflection of a signal and the timing of a pull-down by the negative-voltage pull-down circuit 30 can be accurately matched with each other. In addition, even when a wiring length on the printed circuit board changes and a timing of the reflection fluctuates, the delay period T can be adjusted to T/2, T/3, T/4, or the like.

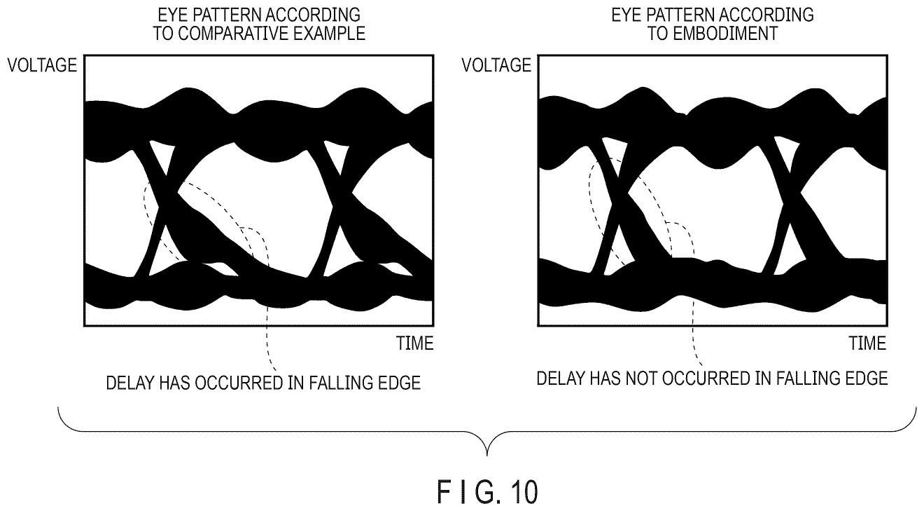

FIG. 10 is a diagram showing an example of eye patterns according to the comparative example and the embodiment.

As shown in FIG. 10, in the eye pattern according to the comparative example, a delay has occurred in a falling edge due to the effect of a reflection of a signal. In this manner, in the comparative example, a favorable eye pattern cannot be obtained due to the effect of a reflection of a signal.

On the other hand, in the eye pattern according to the present embodiment, a delay of the falling edge has improved due to suppression of the effect of a reflection of a signal. In other words, in the present embodiment, a pull-down is performed to a negative voltage at a timing of a reflection of a signal as described above. As a result, the present embodiment is capable of suppressing the effect of a reflection of a signal and obtaining a favorable eye pattern (which results in a favorable signal quality).

As described above, the output buffer Tx according to the present embodiment is capable of suppressing deterioration in signal quality due to an effect of reflection even in communication schemes with small amplitudes.

### Modification

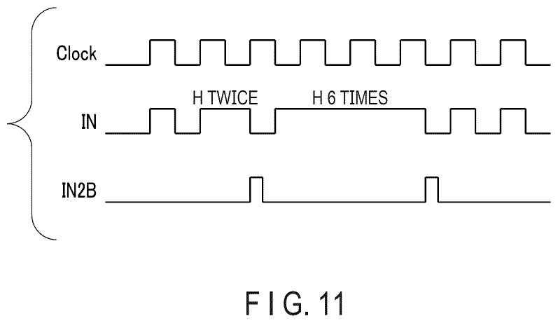

While an edge enhancement or, in other words, a pull-down to a negative voltage is performed when data transitions from a high level to a low level in the embodiment described above, this is not limiting. For example, an edge enhancement may be performed as shown in FIG. 11 in order to reduce intersymbol interference (ISI).

FIG. 11 is a timing chart showing an operation according to a modification.

As shown in FIG. 11, when a high-level signal continues twice in a row, a signal for performing an edge enhancement is outputted when transitioning to a next low level. In a similar manner, when a high-level signal continues six times in a row, a signal for performing an edge enhancement is outputted when transitioning to a next low level.

For example, when a high level and a low level transition occurs each time, a delay is less likely to occur when transitioning from the high level to the low level. On the other hand, when the high level continues two or more times in a row, since data is stabilized at the high level, a delay occurs when transitioning from the high level to the low level.

Therefore, instead of performing an edge enhancement every time data transitions from the high level to the low level, an edge enhancement is performed according to a data pattern such as a high-level signal continuing two or more times in a row. Specifically, when a high-level signal does not continue two or more times in a row as in the case of data “1010”, an edge enhancement is not performed. On the other hand, when a high-level signal continues two or more times in a row as in the case of data “1110”, an edge enhancement is performed when transitioning to a next low level to reduce intersymbol interference.

### Second Embodiment

Next, a second embodiment will be described.

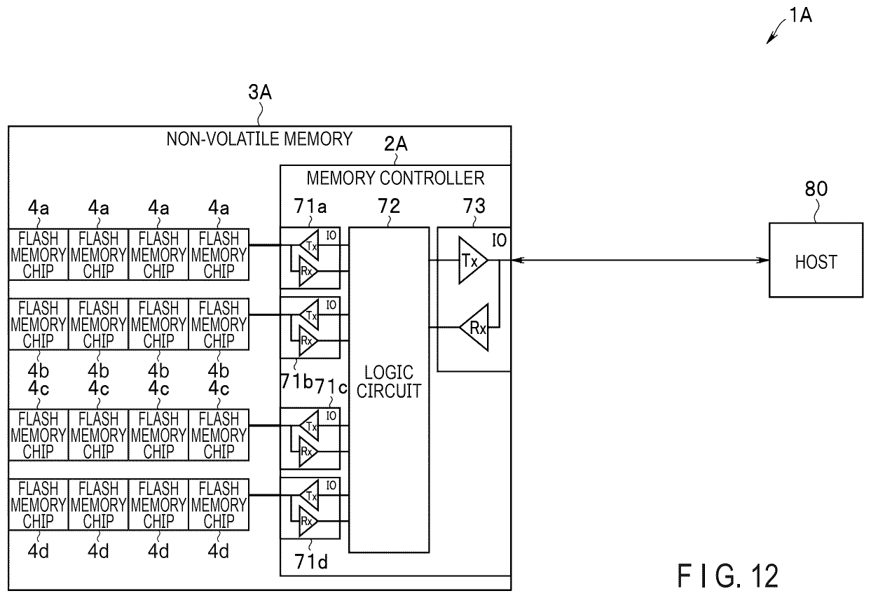

FIG. 12 is a block diagram showing a configuration of a memory system including a semiconductor device according to the second embodiment. Note that, in FIG. 12, similar components to FIG. 1 will be denoted by same reference signs and a description of such components will be omitted.

As shown in FIG. 12, a memory system 1A includes a non-volatile memory 3A and a host 80. The non-volatile memory 3A includes a memory controller 2A and a plurality of flash memory chips 4a, 4b, 4c, and 4d.

The memory controller 2A is implemented as a semiconductor chip. The non-volatile memory 3A has a SiP structure in which the plurality of flash memory chips 4 and the memory controller 2A are stacked and sealed.

The memory controller 2A includes input/output circuits 71a, 71b, 71c, and 71d (hereinafter, referred to as an input/output circuit 71 when no distinction is made among the input/output circuits), a logic circuit 72, and an input/output circuit 73. The input/output circuits 71a, 71b, 71c, and 71d respectively transmit/receive data and various signals to/from the flash memory chips 4a, 4b, 4c, and 4d and the logic circuit 72. The input/output circuit 73 transmits/receives data and various signals to/from the host 80 and the logic circuit 72.

The input/output circuits 71 and 73 respectively include an output buffer (transmission buffer) Tx and a reception buffer Rx. The output buffer Tx according to the first embodiment is applied to the output buffer Tx of the input/output circuit 71. Accordingly, a deterioration in signal quality can also be suppressed even when transmitting data from the memory controller 2A to the flash memory chip 4.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device that is configured to transmit data by a communication scheme in which a signal at a first level has a first voltage margin relative to a first reference voltage that is equal to a ground voltage and the signal at a second level has a second voltage margin relative to a second reference voltage, the second voltage margin being greater than the first voltage margin, the semiconductor device comprising:
an output buffer that is configured to transmit data through the signal according to on/off states of a first transistor group and a second transistor group; and
a control circuit that is configured to perform pull-down of a voltage level of the signal by a third reference voltage that is lower than the first reference voltage when the signal outputted from the output buffer transitions from the second level to the first level.

2. The semiconductor device of claim 1, wherein the control circuit includes:
a delay adjustment circuit that is configured to output an output signal for generating a delay period during which the third reference voltage that is generated from an input signal is set;
a capacitor of which one end is connected to a first node to which the output signal is supplied and another end is connected to a second node; and
a transistor of which a source is connected to the first reference voltage and a drain is connected to the second node.

3. The semiconductor device of claim 2, wherein the control circuit further includes:
a plurality of switches connected in parallel to the capacitor; and
a plurality of operational circuits that is configured to output control signals for controlling on/off states of the plurality of switches, respectively.

4. The semiconductor device of claim 2, wherein the delay adjustment circuit includes:
an inverter circuit that is configured to invert the input signal;
a variable delay circuit that is configured to delay the input signal by a predetermined period; and
a NAND circuit that is configured to calculate a negative AND of an output of the inverter circuit and an output of the variable delay circuit.

5. The semiconductor device of claim 4, wherein the variable delay circuit is configured to control a length of the delay period.

6. The semiconductor device of claim 1, wherein the control circuit is configured to perform the pull-down of the voltage level of the signal by the third reference voltage when the signal outputted from the output buffer transitions from the second level to the first level only after the signal remains at the second level two or more clock transitions in a row.

7. The semiconductor device of claim 1, wherein the third reference voltage is a negative voltage.

8. The semiconductor device of claim 1, wherein the signal is transmitted to a memory controller through a wiring that is shared with another output buffer of the semiconductor device.

9. The semiconductor device of claim 8, wherein the communication scheme is a Low Tapped Termination communication scheme.

10. A memory system, comprising:
a memory chip;
a memory controller that is configured to transmit/receive data to/from the memory chip; and
an interface circuit that is configured to transmit data between the memory chip and the memory controller by a communication scheme in which a signal at a first level has a first voltage margin relative to a first reference voltage that is equal to a ground voltage and the signal at a second level has a second voltage margin relative to a second reference voltage, the second voltage margin being greater than the first voltage margin, the interface circuit including an output buffer that is configured to transmit data through the signal according to on/off states of a first transistor group and a second transistor group, and a control circuit that is configured to perform pull-down of a voltage level of the signal by a third reference voltage that is lower than the first reference voltage when the signal outputted from the output buffer transitions from a second level to the first level.

11. The memory system of claim 10, wherein the control circuit includes:
a delay adjustment circuit that is configured to output an output signal for generating a delay period during which the third reference voltage that is generated from an input signal is set;
a capacitor of which one end is connected to a first node to which the output signal is supplied and another end is connected to a second node; and
a transistor of which a source is connected to the first reference voltage and a drain is connected to the second node.

12. The memory system of claim 11, wherein the control circuit further includes:
a plurality of switches connected in parallel to the capacitor; and
a plurality of operational circuits that is configured to output control signals for controlling on/off states of the plurality of switches, respectively.

13. The memory system of claim 11, wherein the delay adjustment circuit includes:
an inverter circuit that is configured to invert the input signal;
a variable delay circuit that is configured to delay the input signal by a predetermined period; and
a NAND circuit that is configured to calculate a negative AND of an output of the inverter circuit and an output of the variable delay circuit.

14. The memory system of claim 13, wherein the variable delay circuit is configured to control a length of the delay period.

15. The memory system of claim 10, wherein the control circuit is configured to perform the pull-down of the voltage level of the signal by the third reference voltage when the signal outputted from the output buffer transitions from the second level to the first level only after the signal remains at the second level two or more clock transitions in a row.

16. The memory system of claim 10, wherein the third reference voltage is a negative voltage.

17. The memory system of claim 10, wherein the communication scheme is a Low Tapped Termination communication scheme.

18. A method of transmitting a data signal from first and second output buffers of a non-volatile memory device to a memory controller over a common wiring using a communication scheme in which the data signal at a first level has a first voltage margin relative to a first reference voltage that is equal to a ground voltage and the data signal at a second level has a second voltage margin relative to a second reference voltage, the second voltage margin being greater than the first voltage margin, said method comprising:
transmit the data signal according to on/off states of a first transistor group and a second transistor group; and
performing a pull-down of a voltage level of the data signal by a third reference voltage that is lower than the first reference voltage when the data signal outputted from the output buffer transitions from the second level to the first level.

19. The method of claim 18, wherein the third reference voltage is a negative voltage.

20. The method of claim 18, wherein the communication scheme is a Low Tapped Termination communication scheme.
